(19) United States
(12) Patent Application Publication
(10) Pub. No.: US 2026/0324325 A1
(43) Pub. Date: Oct. 15, 2026

(54) ETCHING METHOD AND ETCHING DEVICE

(71) Applicant: Tokyo Electron Limited, Tokyo (JP)

(72) Inventors: Ryo IGOSAWA, Miyagi (JP); Takahiro YONEZAWA, Miyagi (JP)

(73) Assignee: Tokyo Electron Limited, Tokyo (JP)

(21) Appl. No.: 19/691,641

(22) Filed: May 29, 2026

Related U.S. Application Data
(63) Continuation of application No. PCT/JP2024/043398, filed on Dec. 9, 2024.

(30) Foreign Application Priority Data
Dec. 12, 2023 (JP) 2023-208984

(51) Int. Cl. H10P 50/28; H10P 14/60; H10P 50/00; H10P 72/00

(52) U.S. Cl. CPC H10P 50/283; H10P 14/6336; H10P 14/6339; H10P 14/6532; H10P 50/73; H10P 72/0421

(57) ABSTRACT

An etching method includes (a) providing a substrate, the substrate including an etching target layer and a mask on the etching target layer, the mask including at least one opening; (b) forming a deposition layer including a group 14 element on a surface of the substrate; (c) heating the deposition layer to a temperature higher than or equal to a glass transition temperature and performing a thermal reflow treatment on the deposition layer; and (d) etching the etching target layer.

### CROSS-REFERENCE TO RELATED APPLICATIONS

This application is a bypass continuation application of International Application No. PCT/JP 2024/043398 having an international filing date of Dec. 9, 2024 and designating the United States, the International Application being based upon and claiming the benefit of priority from Japanese Patent Application No. 2023-208984, filed on Dec. 12, 2023, the entire contents of each of which are incorporated herein by reference.

### BACKGROUND

### FIELD

Exemplary embodiments of the present disclosure relate to an etching method and an etching device.

### BACKGROUND ART

Patent Literature 1 describes a technique for etching an etching target film including a carbon-containing film.

### CITATION LIST

### Patent Literature

Patent Literature 1: Japanese Unexamined Patent Application Publication No. 2016-21546

### SUMMARY

One or more aspects of the present disclosure are directed to a technique for improving pattern features in an etching target film (hereinafter “film” means the same as “layer”).

An etching method according to one exemplary embodiment of the present disclosure includes (a) providing a substrate, the substrate including an etching target layer and a mask on the etching target layer, the mask including at least one opening; (b) forming a deposition layer including a group 14 element on a surface of the substrate; (c) heating the deposition layer to a temperature higher than or equal to a glass transition temperature and performing a thermal reflow treatment on the deposition layer; and (d) etching the etching target layer.

### BRIEF DESCRIPTION OF DRAWINGS

The scope of the present disclosure is best understood from the following detailed description of exemplary embodiments when read in conjunction with the accompanying drawings.

FIG. 1 is a diagram of a plasma processing system, illustrating an example structure.

FIG. 2 is a diagram of an inductively coupled plasma processing apparatus, illustrating an example structure.

FIG. 3 is a flowchart of an example substrate processing method.

FIG. 4 is a diagram of a substrate in step ST1, illustrating an example cross-sectional structure.

FIG. 5 is a diagram of the substrate in step ST2, illustrating an example cross-sectional structure.

FIG. 6 is a diagram of the substrate in step ST3, illustrating an example cross-sectional structure.

FIG. 7 is a diagram of the substrate in step ST4, illustrating an example cross-sectional structure.

FIG. 8 is a diagram of the substrate in step ST4, illustrating an example cross-sectional structure.

### DETAILED DESCRIPTION

One or more embodiments of the present disclosure will be described below.

In one exemplary embodiment, an etching method includes (a) providing a substrate The substrate includes an etching target film and a mask on the etching target film. The mask includes at least one opening. The etching method includes (b) forming a deposition film containing a group 14 element on a surface of the substrate, (c) heating the deposition film to a temperature higher than or equal to a glass transition temperature and performing a thermal reflow treatment on the deposition film, and (d) etching the etching target film.

In one exemplary embodiment, (c) is performed after (b).

In one exemplary embodiment, (b) includes forming the deposition film by chemical vapor deposition, atomic layer deposition, or molecular layer deposition.

In one exemplary embodiment, (c) includes heating the deposition film using at least one selected from the group consisting of a heater, a lamp, a plasma, electron beams, and ion beams.

In one exemplary embodiment, a cycle including (b) and (c) is repeated.

In one exemplary embodiment, (b) and (c) are performed simultaneously or in an order of (b) and (c).

In one exemplary embodiment, each of (b) and (c) includes exposing the substrate to a plasma generated from a first processing gas including a group 14 element.

In one exemplary embodiment, the first processing gas includes a halogen.

In one exemplary embodiment, (d) is performed after (c).

In one exemplary embodiment, (c) and (d) are performed using a plasma, (c) includes providing no bias signal to a substrate support, and (d) includes providing a bias signal to the substrate support to irradiate the surface of the substrate with ions.

In one exemplary embodiment, a cycle including (c) and (d) is repeated.

In one exemplary embodiment, (c) and (d) are performed simultaneously.

In one exemplary embodiment, each of (c) and (d) includes exposing the substrate to a plasma generated from a second processing gas including an etching gas.

In one exemplary embodiment, the second processing gas includes a halogen.

In one exemplary embodiment, (b), (c), and (d) are performed in an order of (b), (c), and (d).

In one exemplary embodiment, a cycle including (b), (c), and (d) is repeated.

In one exemplary embodiment, (b), (c), and (d) are performed simultaneously.

In one exemplary embodiment, each of (b), (c) and (d) includes exposing the substrate to a plasma generated from a third processing gas including a group 14 element and an etching gas.

In one exemplary embodiment, the third processing gas includes a hydrogen halide gas and a carbon-containing gas.

In one exemplary embodiment, the hydrogen halide gas has a volume percent of 85% or greater of the third processing gas, excluding a noble gas and a nitrogen gas in the third processing gas.

In one exemplary embodiment, the carbon-containing gas has a volume percent of 10% or less of the third processing gas.

In one exemplary embodiment, the carbon-containing gas is free of halogens.

In one exemplary embodiment, the substrate receives ions having an energy level of 1 keV or less.

In one exemplary embodiment, the third processing gas includes a halogen.

In one exemplary embodiment, an etching device includes a chamber, a substrate support in the chamber, a plasma generator, and a controller that performs control operations including (a) providing a substrate onto the substrate support. The substrate includes an etching target film and a mask on the etching target film. The mask includes at least one opening. The control operations include (b) forming a deposition film including a group 14 element on a surface of the substrate, (c) heating the deposition film to a temperature higher than or equal to a glass transition temperature and performing a thermal reflow treatment on the deposition film, and (d) etching the etching target film.

One or more embodiments of the present disclosure will be described below with reference to the drawings. In the drawings, like reference numerals denote the same or like components. Such components will not be described repeatedly. Unless otherwise specified, the positional relationships shown in the drawings are used to describe the vertical, lateral, and other positions. The drawings are not drawn to scale relative to the actual ratio of each component, and the actual ratio is not limited to the ratio in the drawings.

### Example of Plasma Processing System

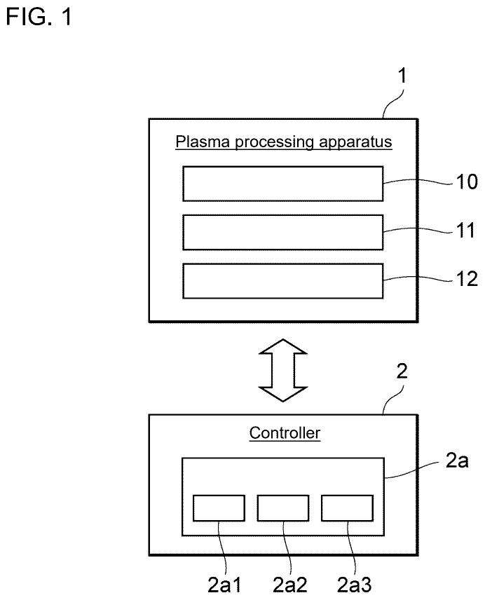

FIG. 1 is a diagram of a plasma processing system, illustrating an example structure. In one embodiment, the plasma processing system includes a plasma processing apparatus 1 and a controller 2 (herein “controller” means the same as “controller circuitry”). The plasma processing system is an example of a substrate processing system. The plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. The plasma processing chamber 10 also has at least one gas inlet for supplying at least one processing gas into the plasma processing space and at least one gas outlet for exhausting the gas from the plasma processing space. The gas inlet is connected to a gas supply 20 (described later). The gas outlet is connected to an exhaust system 40 (described later). The substrate support 11 is located in the plasma processing space and has a substrate support surface for supporting a substrate.

The plasma generator 12 generates a plasma from at least one processing gas supplied into the plasma processing space. The plasma generated in the plasma processing space may be, for example, a capacitively coupled plasma (CCP), an inductively coupled plasma (ICP), an electron cyclotron resonance (ECR) plasma, a helicon wave plasma (HWP), or a surface wave plasma (SWP). The plasma generator 12 may be one of various plasma generators including an alternating current (AC) plasma generator and a direct current (DC) plasma generator. In one embodiment, an AC signal (AC power) used in the AC plasma generator has a frequency in a range of 100 kHz to 10 GHz. Thus, the AC signal may be a radio-frequency (RF) signal or a microwave signal. In one embodiment, the RF signal has a frequency in a range of 100 kHz to 150 MHz.

The controller 2 processes computer-executable instructions that cause the plasma processing apparatus 1 to perform various steps described in one or more embodiments of the present disclosure. The controller 2 may cause the components of the plasma processing apparatus 1 to perform the various steps described herein. In one embodiment, some or all of the components of the controller 2 may be included in the plasma processing apparatus 1. The controller 2 may include, for example, a computer 2a. The computer 2a may include, for example, a central processing unit (CPU) 2a1, a storage 2a2, and a communication interface 2a3. The processor 2a1 may perform various control operations by loading programs from the storage 2a2 and executing the loaded programs. The program may be prestored in the storage 2a2 or may be obtained through a medium as appropriate. The obtained program is stored into the storage 2a2 to be loaded from the storage 2a2 and executed by the processor 2a1. The medium may be one of various storage media readable by the computer 2a or a communication line connected to the communication interface 2a3. The storage 2a2 may include a random-access memory (RAM), a read-only memory (ROM), a hard disk drive (HDD), a solid-state drive (SSD), or a combination of these. The communication interface 2a3 may communicate with the plasma processing apparatus 1 through a communication line such as a local area network (LAN). The controller/controller circuitry 2 can be programmable circuitry (e.g., embedded processor) or fixed circuitry (e.g., ASIC or PAL). In an exemplary embodiment, the controller/controller circuitry 2 can include one or more programmable processors/controllers.

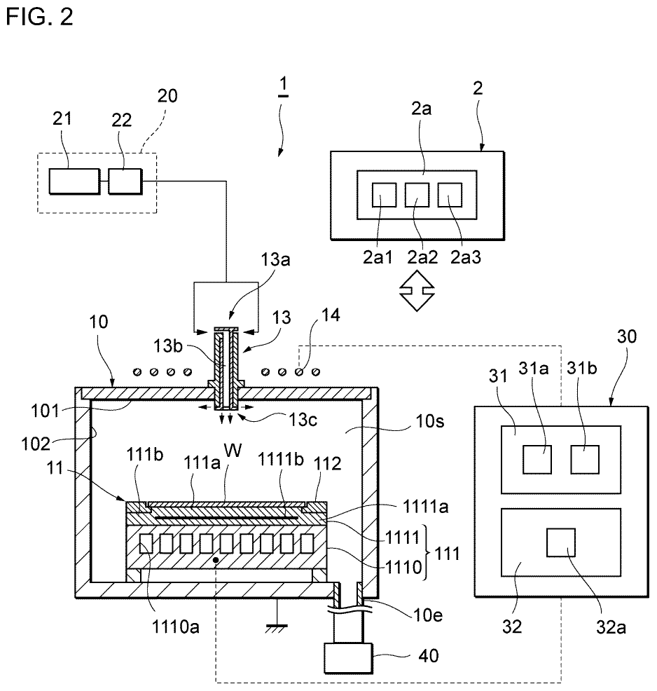

An example structure of an inductively coupled plasma processing apparatus as an example of the plasma processing apparatus 1 will be described below. FIG. 2 is a diagram of the inductively coupled plasma processing apparatus, illustrating an example structure. The inductively coupled plasma processing apparatus 1 includes the plasma processing chamber 10, the gas supply 20, a power supply 30, and the exhaust system 40. The plasma processing chamber 10 includes a dielectric window 101. The plasma processing apparatus 1 also includes the substrate support 11, a gas guide unit, and an antenna 14. The substrate support 11 is located in the plasma processing chamber 10. The antenna 14 is located on or above the plasma processing chamber 10 (more specifically, on or above the dielectric window 101). The plasma processing chamber 10 has a plasma processing space 10s defined by the dielectric window 101, a sidewall 102 of the plasma processing chamber 10, and the substrate support 11. The plasma processing chamber 10 is grounded.

The substrate support 11 includes a body 111 and a ring assembly 112. The body 111 includes a central portion 111a for supporting a substrate W and an annular portion 111b for supporting the ring assembly 112. A wafer is an example of the substrate W. The annular portion 111b of the body 111 surrounds the central portion 111a of the body 111 as viewed in plan. The substrate W is placeable on the central portion 111a of the body 111. The ring assembly 112 is located on the annular portion 111b of the body 111 to surround the substrate W on the central portion 111a of the body 111. Thus, the central portion 111a is also referred to as a substrate support surface for supporting the substrate W. The annular portion 111b is also referred to as a ring support surface for supporting the ring assembly 112.

In one embodiment, the body 111 includes a base 1110 and an electrostatic chuck (ESC) 1111. The base 1110 includes a conductive member. The conductive member in the base 1110 may function as a bias electrode. The ESC 1111 is located on the base 1110. The ESC 1111 includes a ceramic member 1111a and an electrostatic electrode 1111b located inside the ceramic member 1111a. The ceramic member 1111a includes the central portion 111a. In one embodiment, the ceramic member 1111a also includes the annular portion 111b. The annular portion 111b may be included in another member surrounding the ESC 1111, such as an annular ESC or an annular insulating member. In this case, the ring assembly 112 may be located on the annular ESC or the annular insulating member, or may be located on both the ESC 1111 and the annular insulating member. An RF electrode or a DC electrode may also be located inside the ceramic member 1111a. In this case, the RF electrode or the DC electrode functions as a bias electrode. The conductive member inside the base 1110 and one of the RF electrode or the DC electrode may function as two bias electrodes.

The ring assembly 112 includes one or more annular members. In one embodiment, the one or more annular members include one or more edge rings and at least one cover ring. The edge rings are formed from a conductive material or an insulating material. The cover ring is formed from an insulating material.

The substrate support 11 may include a temperature controller that adjusts the temperature of at least one of the ESC 1111, the ring assembly 112, or the substrate to a target temperature. The temperature controller may include a heater, a heat transfer medium, a channel 1110a, or a combination of these. The channel 1110a carries a heat transfer fluid such as brine or a gas. In one embodiment, the channel 1110a is defined inside the base 1110, and one or more heaters are located inside the ceramic member 1111a in the ESC 1111. The substrate support 11 may include a heat transfer gas supply to supply a heat transfer gas into a space between the back surface of the substrate W and the central portion 111a.

The gas guide unit introduces at least one processing gas from the gas supply 20 into the plasma processing space 10s. In one embodiment, the gas guide unit includes a central gas injector (CGI) 13. The CGI 13 is located above the substrate support 11 and installed in a central opening in the dielectric window 101. The CGI 13 has at least one gas inlet 13a, at least one gas channel 13b, and at least one gas guide 13c. The processing gas supplied to the gas inlet 13a passes through the gas channel 13b and is introduced into the plasma processing space 10s through the gas guide 13c. The gas guide unit may include, in addition to or instead of the CGI 13, one or more side gas injectors (SGIs) attached to one or more openings in the side-wall 102.

The gas supply 20 may include at least one gas source 21 and at least one flow controller 22. In one embodiment, the gas supply 20 supplies at least one processing gas from each gas source 21 to the gas guide unit through the corresponding flow controller 22. The flow controller 22 may be, for example, a mass flow controller or a pressure-based flow controller. The gas supply 20 may further include at least one flow rate modulator that causes at least one processing gas to be supplied at a modulated flow rate or in a pulsed manner.

The power supply 30 includes an RF power supply 31 coupled to the plasma processing chamber 10 through at least one impedance matching circuit. The RF power supply 31 provides at least one RF signal (RF power), such as a source RF signal or a bias RF signal, to at least one bias electrode and the antenna 14. This generates a plasma from at least one processing gas supplied into the plasma processing space 10s. The RF power supply 31 may thus function as at least a part of the plasma generator 12. A bias RF signal is provided to at least one bias electrode to generate a bias potential in the substrate W, thus drawing ions in the generated plasma toward the substrate W.

In one embodiment, the RF power supply 31 includes a first RF generator 31a and a second RF generator 31b. The first RF generator 31a is coupled to the antenna 14 through at least one impedance matching circuit to generate a source RF signal (source RF power) for plasma generation. In one embodiment, the source RF signal has a frequency in a range of 10 to 150 MHz. In one embodiment, the first RF generator 31a may generate multiple source RF signals with different frequencies. The one or more generated source RF signals are provided to the antenna 14.

The second RF generator 31b is coupled to at least one bias electrode through at least one impedance matching circuit to generate a bias RF signal (bias RF power). The frequency of the bias RF signal may be the same as or different from the frequency of the source RF signal. In one embodiment, the bias RF signal has a lower frequency than the source RF signal. In one embodiment, the bias RF signal has a frequency in a range of 100 kHz to 60 MHz. In one embodiment, the second RF generator 31b may generate multiple bias RF signals with different frequencies. The one or more generated bias RF signals are provided to at least one bias electrode. In various embodiments, at least one of the source RF signal or the bias RF signal may be pulsed.

The power supply 30 may include a DC power supply 32 coupled to the plasma processing chamber 10. The DC power supply 32 includes a bias DC generator 32a. In one embodiment, the bias DC generator 32a is coupled to at least one bias electrode to generate a bias DC signal. The generated bias DC signal is applied to at least one bias electrode.

In various embodiments, the bias DC signal may be pulsed. In this case, the sequence of voltage pulses based on DC is applied to at least one bias electrode. The voltage pulses may have rectangular, trapezoidal, or triangular pulse waveforms, or a combination of these. In one embodiment, a waveform generator for generating a sequence of voltage pulses based on DC signals is coupled between the bias DC generator 32a and at least one bias electrode. Thus, the bias DC generator 32a and the waveform generator form a voltage pulse generator. The voltage pulses may have positive polarity or negative polarity. The sequence of voltage pulses may include one or more positive voltage pulses and one or more negative voltage pulses within one cycle. The power supply 30 may include the bias DC generator 32a in addition to the RF power supply 31 or in place of the second RF generator 31b.

The antenna 14 includes one or more coils. In one embodiment, the antenna 14 may include an outer coil and an inner coil that are coaxial with each other. In this case, the RF power supply 31 may be coupled to both the outer coil and the inner coil, or either the outer coil or the inner coil. When the RF power supply 31 is coupled to both the outer coil and the inner coil, a single RF generator may be coupled to both the outer coil and the inner coil, or separate RF generators may be coupled respectively to the outer coil and the inner coil.

The exhaust system 40 is connectable to, for example, a gas outlet 10e in the bottom of the plasma processing chamber 10. The exhaust system 40 may include a pressure control valve and a vacuum pump. The pressure control valve regulates the pressure in the plasma processing space 10s. The vacuum pump may be a turbomolecular pump, a dry pump, or a combination of these.

### Example of Etching Method

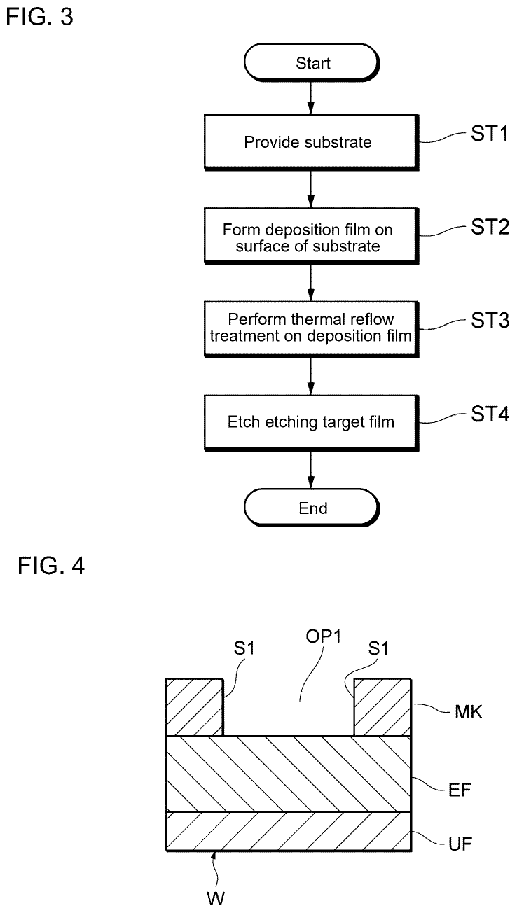

FIG. 3 is a flowchart of an example of an etching method (hereafter also referred to as a processing method) according to an exemplary embodiment. As shown in FIG. 3, the processing method according to one embodiment includes step ST1 of providing a substrate, step ST2 of forming a deposition film on the surface of the substrate, step ST3 of performing a thermal reflow treatment on the deposition film, and step ST4 of etching an etching target film. The processing in each step may be performed in the plasma processing system shown in FIG. 2. The controller 2 causes the components of the plasma processing apparatus 1 to perform the processing method on the substrate W.

### Step ST1: Providing Substrate

In step ST1, the substrate W is provided into the plasma processing chamber 10 (hereafter also referred to as a chamber 10) as shown in FIG. 2. In one embodiment, the substrate W is loaded into the chamber 10 with a transfer arm, placed onto the substrate support 11 with a lifter, and clamped on the substrate support 11.

FIG. 4 is a diagram of the substrate W in step ST1, illustrating an example cross-sectional structure. The substrate W includes an etching target film EF and a mask MK stacked on an underlying film UF in this order from below. The substrate W may be used for manufacturing semiconductor devices. Examples of the semiconductor devices include a memory device such as a dynamic RAM (DRAM) and a three-dimensional NOT-AND (3D-NAND) flash memory, and a logic device.

The mask MK may be a film that masks the etching target film EF in etching. The mask MK may have a sidewall S1 defining at least one opening OP1 on the etching target film EF. More specifically, the mask MK may include at least one opening OP1. The opening OP1 may be a space on the etching target film EF, surrounded by the sidewall S1 of the mask MK. In other words, the upper surface of the etching target film EF may include a portion covered with the mask MK and a portion exposed through the bottom of the opening OP1.

The opening OP1 may have any feature in a plan view of the substrate W, or in other words, when the substrate W is viewed from the top to the bottom in FIG. 4. The opening feature may be, for example, a circle, an oval, a rectangle, a line, or a combination of one or more of these features. The mask MK may have multiple sidewalls S1, which may define multiple openings OP1. The openings OP1 may be slits arranged in a pattern of lines and spaces at regular intervals or different intervals. The openings OP1 may be holes in a patterned array.

The mask MK may be an organic resist film, an amorphous carbon layer (ACL), a metal-containing resist film, or a metal oxide resist film. The mask MK may be a single layer mask including one layer or a multilayer mask including two or more layers.

The etching target film EF may be, for example, a silicon oxynitride (SiON) film, a spin-on carbon (SOC) film, a silicon oxide (SiO₂) film, a silicon carbide (SiC) film, or an amorphous silicon film.

The underlying film UF may be, for example, a silicon wafer or an organic film, a dielectric film, a metal film, or a semiconductor film on the silicon wafer. The underlying film UF may include multiple films stacked on one another.

The films included in the substrate W may each be formed by any method. The underlying film UF, the etching target film EF, and the mask MK may each be formed by chemical vapor deposition (CVD), atomic layer deposition (ALD), molecular layer deposition (MLD), physical vapor deposition (PVD), spin coating, or other methods. The opening OP1 in the mask MK may be formed by etching. The opening OP1 in the mask MK may also be formed by lithography. Each film may be a flat film or an uneven film. The substrate W may further include another film under the underlying film UF.

The process of forming the underlying film UF, the etching target film EF, and the mask MK in the substrate W may be at least partially performed in the chamber 10 as part of step ST1. For example, the opening OP1 in the mask MK is formed by etching in step ST1. In this case, etching the mask MK in step ST1 and processing in steps ST2, ST3, and ST4 (described later) may be sequentially performed in the chamber 10. In one embodiment, all or some of the films in the substrate W may be formed in an apparatus or a chamber external to the plasma processing apparatus 1 and then provided into the chamber 10.

In one embodiment, after the substrate W is provided onto the substrate support 11, the temperature of the substrate support 11 or the substrate W is controlled to be a given temperature by the temperature controller. Controlling the temperature of the substrate support 11 or the substrate W to be a given temperature includes causing the temperature of the heat transfer fluid flowing in the channel 1110a or the temperature of the heater to be a given temperature, or to be a temperature different from the given temperature. The given temperature may be in a range of 60 to −50 °C inclusive. The temperature of the substrate support 11 or the substrate W may start to be controlled to be the given temperature before, after, or at the same time as the substrate W is placed on the substrate support 11. The temperature of the substrate support 11 or the substrate W may be changed in each of steps ST1, ST2, ST3, and ST4.

### Step ST2: Forming Deposition Film

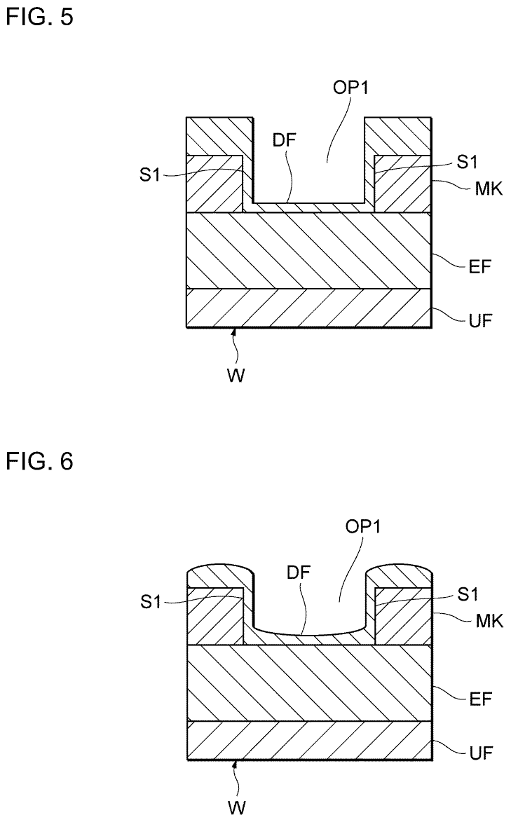

FIG. 5 is a diagram of the substrate W including the deposition film DF formed in step ST2, illustrating an example cross-sectional structure. In one embodiment, the substrate W is exposed to a first processing gas to form the deposition film DF on the surface of the substrate W in step ST2. The deposition film DF may be formed by plasma CVD.

In one embodiment, the first processing gas is supplied into the chamber 10 through the CGI 13 shown in FIG. 2 in step ST2. The temperature of the substrate support 11 or the substrate W may be controlled to be a first temperature. The first temperature may be in a range of 80 to −50 °C inclusive or in a range of 80 to 0 °C inclusive. The pressure in the chamber 10 may be adjusted to be a first pressure. The first pressure may be in a range of 1 to 1000 mTorr inclusive or in a range of 50 to 500 mTorr inclusive.

The first processing gas may include a group 14 element. The group 14 element may be one of C, Si, Ge, or Sn. The first processing gas may include, as a gas containing a group 14 element, at least one selected from the group consisting of a CF-based gas, a CHF-based gas, a CBr-based gas, a CHBr-based gas, an SiCl-based gas, an SiH-based gas, an SiF-based gas, and an SiBr-based gas. The CF-based gas (fluorocarbon gas) may include at least one selected from the group consisting of a CF₄ gas, a C₂F₂ gas, a C₂F₄ gas, a C₃F₆ gas, a C₃F₈ gas, a C₄F₆ gas, a C₄F₈ gas, and a C₅F₈ gas. The CHF-based gas (hydrofluorocarbon gas) may include at least one selected from the group consisting of a CH₂F₂ gas, a CH₃F gas, and a CHF₃ gas.

The first processing gas may further include a halogen. The first processing gas may include a single gas of a halogen or include a hydrogen halide. The halogen may be one of F, Cl, Br, and I. The first processing gas may include, as a hydrogen halide, at least one selected from the group consisting of an HF gas, an HCl gas, an HBr gas, and an HI gas. The first processing gas may further include an inert gas. The inert gas may be a noble gas such as an Ar gas, a He gas, or a Kr gas, or may be an N₂ gas.

In one embodiment, a plasma is generated from the first processing gas supplied into the chamber 10. In this case, the first RF generator 31a provides a source RF signal to the antenna 14. This generates an RF electric field between the antenna 14 and the substrate support 11, generating a plasma from the first processing gas in the plasma processing space 10s. The source RF signal may have a frequency of 10 MHz or higher. The source RF signal may have first power. The first power may have a level of 1 kW or higher.

A bias signal may be provided to the substrate support 11 during plasma generation. The bias signal may be a bias RF signal provided from the RF power supply 31 or a bias DC signal provided from the DC power supply 32. In this case, a bias potential is generated between the plasma and the substrate W. Ions and dissociated neutral species in the plasma are drawn toward the substrate W.

As shown in FIG. 5, ions or dissociated neutral species in the plasma are deposited on the surface of the substrate W to form the deposition film DF. The deposition film DF may be formed on the upper surface of the mask MK, the sidewall S1 of the opening OP1, and the upper surface of the etching target film EF exposed through the opening OP1.

The deposition film DF may be formed, in step ST2, by one of various methods such as ALD, MLD, and other methods of CVD, other than plasma CVD.

### Step ST3: Performing Thermal Reflow Treatment on Deposition Film

FIG. 6 is a diagram of the substrate W including the deposition film DF subjected to a thermal reflow treatment in step ST3, illustrating an example cross-sectional structure. In one embodiment, the deposition film DF is heated to a temperature higher than or equal to a glass transition temperature and subjected to the thermal reflow treatment in step ST3.

In one embodiment, a plasma may be used as a heat source to heat the deposition film DF in step ST3. In step ST3, for example, a plasma may be generated from a second processing gas supplied through the CGI 13 into the chamber 10. In this case, the first RF generator 31a provides a source RF signal to the antenna 14. This generates an RF electric field between the antenna 14 and the substrate support 11, generating a plasma from the second processing gas in the plasma processing space 10s. The source RF signal may have a frequency of 10 MHz or higher. The source RF signal may have second power. The second power may have a level of 300 W or higher, or 500 W or higher. The second power may be higher than the first power. The temperature of the substrate support 11 or the substrate W may be controlled to be a second temperature. The second temperature may be 60 °C or lower, or 50 °C or lower. The pressure in the chamber 10 may be adjusted to be a second pressure. The second pressure may be 1000 Torr or lower. In step ST3, no bias signal may be provided to the substrate support 11.

The second processing gas supplied into the chamber 10 may include a halogen. The second processing gas may include a hydrogen halide. The second processing gas may include, as a hydrogen halide, at least one selected from the group consisting of an HF gas, an HCl gas, an HBr gas, and an HI gas. The second processing gas may be the same as the first processing gas.

The deposition film DF is heated to a temperature higher than or equal to the glass transition temperature with heat from the plasma and subjected to the thermal reflow treatment. In this state, the deposition film DF has lower stiffness and viscosity, thus being flowable (in a state of soft rubber). This allows the deposition film DF to flow, smoothing its surface. A webpage (www. sciencedirect. com/science/article/pii/S0167931722001332) can be referred to for thermal reflow treatment.

The heat source for heating the deposition film DF in step ST3 may be a heater, a lamp, electron beams, or ion beams, other than a plasma. The heater may be located in the substrate support 11. The lamp may be an infrared lamp located in the chamber 10. When electron beams or ion beams are used as a heat source, an electron beam irradiator or an ion beam irradiator may be located in the chamber 10.

Steps ST2 and ST3 may be performed simultaneously or sequentially in this order. In this state, the first processing gas (second processing gas) may include a group 14 element and a halogen. In the processing method, a cycle including steps ST2 and ST3 may be repeated multiple times.

### Step St4: Etching

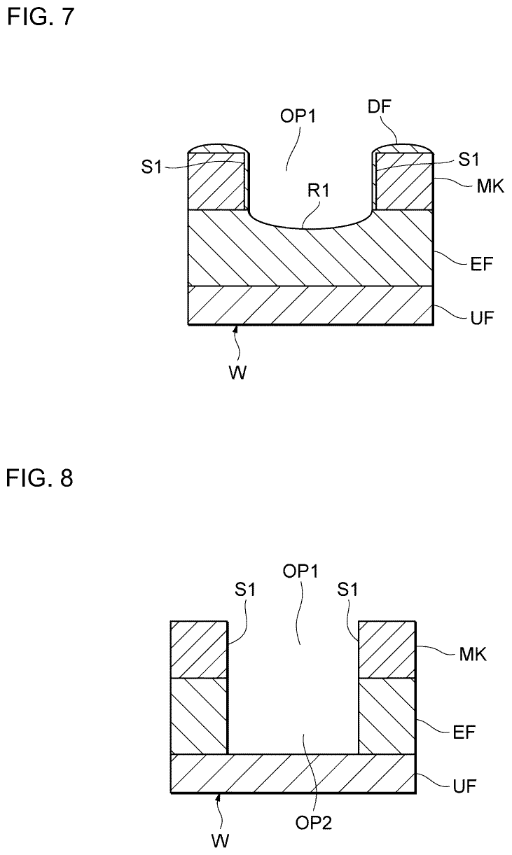

FIG. 7 is a diagram of the substrate W in step ST4, illustrating an example cross-sectional structure. FIG. 8 is a diagram of the substrate W including the etching target film EF etched in step ST4, illustrating an example cross-sectional structure. In one embodiment, the etching target film EF is etched in step ST4. The upper surface of the etching target film EF exposed through the opening OP1 is etched. As shown in FIG. 7, the etching proceeds in the depth direction, forming a recess R1 in the etching target film EF. As shown in FIG. 8, the etching further proceeds, forming an opening OP2 in the etching target film EF.

In one embodiment, an etching gas is supplied into the chamber 10 through the CGI 13 shown in FIG. 2 in step ST4. The etching gas may include a gas including carbon and fluorine. The etching gas may include a CF-based gas or a CHF-based gas. The CF-based gas (fluorocarbon gas) may be at least one selected from the group consisting of a C₄F₆ gas, a C₄F₈ gas, a C₃F₈ gas, a CF₄ gas, a C₂F₂ gas, a C₂F₄ gas, a C₃F₆ gas, and a C₅F₈ gas. The CHF-based gas (hydrofluorocarbon gas) may be at least one selected from the group consisting of a CHF₃ gas, a CH₂F₂ gas, a CH₃F gas, a C₃H₂F₄ gas, a C₄H₂F₆ gas, a C₂HF₅ gas, a C₂H₂F₄ gas, a C₂H₃F₃ gas, a C₂H₄F₂ gas, a C₃HF₇ gas, a C₃H₂F₂ gas, a C₃H₂F₆ gas, a C₃H₃F₅ gas, a C₄H₅F₅ gas, a C₄H₂F₈ gas, a C₅H₂F₆ gas, a C₅H₂F₁₀ gas, and a C₅H₃F₇ gas. The etching gas may include at least one selected from the group consisting of an SiH-based gas, an SiF-based gas, and an SiBr-based gas.

A plasma is generated from an etching gas supplied into the chamber 10. In this case, a source RF signal is provided to the antenna 14. This generates an RF electric field between the antenna 14 and the substrate support 11, generating a plasma from the etching gas in the plasma processing space 10s. The source RF signal may have a frequency of 10 MHz or higher. The temperature of the substrate support 11 or the substrate W may be controlled to be a third temperature. The third temperature may be 60 °C or lower. The pressure in the chamber 10 may be adjusted to be a third pressure. The third pressure may be 1000 Torr or lower.

A bias signal may be provided to the substrate support 11. The bias signal may be a bias RF signal provided from the RF power supply 31 or a bias DC signal provided from the DC power supply 32. In this case, a bias potential is generated between the plasma and the substrate W. Active species such as ions and radicals in the plasma are drawn toward the substrate W to etch the etching target film EF in the depth direction. The bias RF signal may have a power level (effective value) of 500 W or lower. The bias signal provided in step ST4 may be higher than the bias signal provided in step ST2.

After step ST4, the substrate W may be unloaded outside the chamber 10. In one embodiment, the substrate W may be unloaded outside the chamber 10 from the substrate support 11 with the lifter and the transfer arm.

Steps ST3 and ST4 may be performed simultaneously or sequentially in this order. When steps ST3 and ST4 are performed simultaneously, the second processing gas may include an etching gas. When steps ST3 and ST4 are performed sequentially, no bias signal may be provided to the substrate support 11 in the generated plasma in step ST3, and a bias signal may be provided to the substrate support 11 to irradiate the surface of the substrate W with ions in the generated plasma in step ST4. More specifically, step ST3 may be changed to step ST4 by switching between supplying a bias signal to the substrate support 11 and stopping the supply of the bias signal to the substrate support 11.

In the present processing method, a cycle including steps ST3 and ST4 may be repeated multiple times. In this case, steps ST3 and ST4 may be alternately changed to each other by switching between supplying a bias signal to the substrate support 11 and stopping the supply of the bias signal to the substrate support 11.

Steps ST2, ST3, and ST4 may be performed simultaneously or sequentially in this order. When steps ST2, ST3, and ST4 are performed simultaneously, the substrate W may be exposed to a plasma generated from the third processing gas including a group 14 element and an etching gas. The third processing gas may further include a halogen. In the processing method, a cycle including steps ST2, ST3, and ST4 may be repeated multiple times.

In an exemplary embodiment, the substrate processing method includes step ST12 of providing the substrate W, step ST2 of forming the deposition film DF including a group 14 element on the surface of the substrate W, a step of heating the deposition film DF to a temperature higher than or equal to the glass transition temperature and performing the thermal reflow treatment on the deposition film DF, and a step of etching the etching target film EF. Performing the thermal reflow treatment on the deposition film DF smooths the surface of the deposition film DF. The patterned surface of the mask MK thus has lower roughness. When the mask MK includes holes as its pattern, the holes have higher roundness. This improves the pattern features (roughness and roundness) in the etching target film.

At least one of the first processing gas, the second processing gas, or the third processing gas including a halogen allows an appropriate thermal reflow treatment to be performed on the deposition film DF. This improves the pattern features (roughness and roundness) in the etching target film.

When steps ST2, ST3, and ST4 are performed simultaneously, the third processing gas may include a hydrogen halide gas and a carbon-containing gas. The hydrogen halide gas is an example of an etching gas. The carbon-containing gas is an example of a gas including a group 14 element. The hydrogen halide gas may have a volume percent of 85% or greater of the third processing gas, excluding a noble gas and a nitrogen gas. The carbon-containing gas may have a volume percent of 10% or less of the third processing gas. The carbon-containing gas may have a volume percent of 10% or less of the third processing gas, excluding the noble gas and the nitrogen gas.

The hydrogen halide gas may include at least one selected from the group consisting of an HF gas, an HCl gas, an HBr gas, and an HI gas.

The carbon-containing gas may include at least one selected from the group consisting of a CH-based gas, a CF-based gas, a CHF-based gas, a CBr-based gas, and a CHBr-based gas. The CH-based gas may be a CH₄ gas. The carbon-containing gas may be a halogen-free gas.

The third processing gas may further include an inert gas. The inert gas may be a noble gas such as an Ar gas, a He gas, or a Kr gas, or may be an N₂ gas.

When steps ST2, ST3, and ST4 are performed simultaneously in the present embodiment, the third processing gas is first supplied into the chamber 10. The third processing gas is supplied into the chamber 10 through the CGI 13 shown in FIG. 2.

A plasma is then generated from the third processing gas supplied into the chamber 10. In this case, a source RF signal is provided to the antenna 14. This generates an RF electric field between the antenna 14 and the substrate support 11, generating a plasma from the third processing gas in the plasma processing space 10s. The source RF signal may have a power level of 500 W or higher, or 1 kW or higher. The temperature of the substrate support 11 or the substrate W may be set to 30 °C or lower, or 10 °C or lower. The pressure in the chamber 10 may be adjusted to be 100 mTorr or lower, or 80 mTorr or lower.

A bias signal may be provided to the substrate support 11. The bias signal may be a bias RF signal provided from the RF power supply 31 or a bias DC signal provided from the DC power supply 32. The bias signal may have a power level of 50 W or lower. Ions incident on the substrate may have an energy level of 1 keV or less.

In the present embodiment, forming the deposition film DF, performing the thermal reflow treatment on the deposition film DF, and etching the etching target film EF are performed simultaneously. Performing these processes using a plasma generated from the third processing gas including a hydrogen halide gas and a carbon-containing gas can improve the pattern features (roughness and roundness) in the etching target film.

The processing in the present embodiment may be used for etching a fine pattern of lines and spaces with a pitch of 60 nm or less in the etching target film. The processing in the present embodiment may be used for etching using an extreme ultraviolet (EUV) mask or a resist film (a metal oxide resist film or a chemically amplified resist film) as a mask. The plasma may be a remote plasma generated from the third processing gas outside the chamber and supplied into the chamber.

### Example 1

A substrate W including an etching target film EF of a silicon oxynitride film and a mask MK of a resist film (organic film) was prepared. Under conditions 1 and 2 below, steps ST2, ST3, and ST4 were performed simultaneously to perform etching and form a pattern of lines and spaces in the etching target film EF.

### Condition 1

Gas species: an HF gas (95 vol % excluding a noble gas of an Ar gas), a CH₄ gas (5 vol % excluding a noble gas of an Ar gas), and an Ar gas
Pressure: 10 mTorr
Temperature: 0 °C
Source RF power: 1 kW
Bias power: 30 W

### Condition 2

Gas species: a CF₄ gas (100 vol % excluding a noble gas of an Ar gas) and an Ar gas
Pressure: 30 mTorr
Temperature: 30 °C
Source RF power: 150 W/50 W (36 cycles)
Bias power: 50 W/245 W (36 cycles)

The etching target film EF etched under Condition 1 had a pattern of lines and spaces with a line width roughness (LWR) of 0.96, a space width roughness (SWR) of 0.87, and a line edge roughness (LER) of 0.93, where the LWR, SWR, and LER of the pattern of lines and spaces in the etching target film EF were 1 under Condition 2.

### Example 2

A substrate W including an etching target film EF of a silicon oxynitride film and a mask MK of a resist film (organic film) was prepared. Under conditions 3 and 4 below, steps ST2, ST3, and ST4 were performed simultaneously to perform etching and form a pattern of holes in the etching target film EF.

### Condition 3

Gas species: an HF gas (96 vol % excluding a noble gas), a C₄F₆ gas (4 vol % excluding a noble gas of an Ar gas), and an Ar gas
Pressure: 10 mTorr
Temperature: 0 °C
RF power: 1 kW
Bias power: 30 W

### Condition 4

Gas species: a CHF₃ gas and a CH₃F gas (the carbon-containing gases being 66 vol % excluding a noble gas of an Ar gas), an NF₃ gas, and an Ar gas
Pressure: 10 mTorr
Temperature: 30 °C
Source RF power: 1 kW
Bias Power: 50 W

The etching target film EF etched under Condition 3 had a pattern of holes with a contact edge roughness (CER) of 0.53, where the CER of the pattern of holes in the etching target film EF was 1 under Condition 4.

The technique according to one exemplary embodiment of the present disclosure improves pattern features in the etching target film.

The processing method according to the above embodiments may be performed in other types of plasma processing apparatuses such as a plasma processing apparatus that generates a capacitively coupled plasma, a plasma processing apparatus that generates an ECR plasma, a plasma processing apparatus that generates a helicon wave plasma, or a plasma processing apparatus that generates a surface wave plasma, other than the inductively coupled plasma processing apparatus.

The embodiments of the present disclosure further include the aspects described below.

### Aspect 1

An etching method, comprising:
(a) providing a substrate, the substrate including an etching target film and a mask on the etching target film, the mask including at least one opening;
(b) forming a deposition film comprising a group 14 element on a surface of the substrate;
(c) heating the deposition film to a temperature higher than or equal to a glass transition temperature and performing a thermal reflow treatment on the deposition film; and
(d) etching the etching target film.

### Aspect 2

The etching method according to aspect 1, wherein
(c) is performed after (b).

### Aspect 3

The etching method according to aspect 2, wherein
(b) includes forming the deposition film by chemical vapor deposition, atomic layer deposition, or molecular layer deposition.

### Aspect 4

The etching method according to aspect 2 or aspect 3, wherein
(c) includes heating the deposition film using at least one selected from the group consisting of a heater, a lamp, a plasma, electron beams, and ion beams.

### Aspect 5

The etching method according to any one of aspects 2 to 4, wherein
a cycle including (b) and (c) is repeated.

### Aspect 6

The etching method according to aspect 1, wherein
(b) and (c) are performed simultaneously or in an order of (b) and (c).

### Aspect 7

The etching method according to aspect 6, wherein
each of (b) and (c) includes exposing the substrate to a plasma generated from a first processing gas including a group 14 element.

### Aspect 8

The etching method according to aspect 7, wherein
the first processing gas includes a halogen.

### Aspect 9

The etching method according to aspect 1, wherein
(d) is performed after (c).

### Aspect 10

The etching method according to aspect 9, wherein
(c) and (d) are performed using a plasma,
(c) includes providing no bias signal to a substrate support, and
(d) includes providing a bias signal to the substrate support to irradiate the surface of the substrate with ions.

### Aspect 11

The etching method according to aspect 9 or aspect 10, wherein
a cycle including (c) and (d) is repeated.

### Aspect 12

The etching method according to aspect 1, wherein
(c) and (d) are performed simultaneously.

### Aspect 13

The etching method according to aspect 12, wherein
each of (c) and (d) includes exposing the substrate to a plasma generated from a second processing gas including an etching gas.

### Aspect 14

The etching method according to aspect 13, wherein
the second processing gas includes a halogen.

### Aspect 15

The etching method according to aspect 1, wherein (b), (c), and (d) are performed in an order of (b), (c), and (d).

### Aspect 16

The etching method according to aspect 15, wherein
a cycle including (b), (c), and (d) is repeated.

### Aspect 17

The etching method according to aspect 1, wherein
(b), (c), and (d) are performed simultaneously.

### Aspect 18

The etching method according to aspect 17, wherein
each of (b), (c) and (d) includes exposing the substrate to a plasma generated from a third processing gas including a group 14 element and an etching gas.

### Aspect 19

The etching method according to aspect 18, wherein
the third processing gas includes a halogen.

### Aspect 20

The etching method according to aspect 18, wherein
the third processing gas includes a hydrogen halide gas and a carbon-containing gas.

### Aspect 21

The etching method according to aspect 20, wherein
the hydrogen halide gas has a volume percent of 85% or greater of the third processing gas, excluding a noble gas and a nitrogen gas in the third processing gas.

### Aspect 22

The etching method according to aspect 20 or aspect 21, wherein
the carbon-containing gas has a volume percent of 10% or less of the third processing gas.

### Aspect 23

The etching method according to any one of aspects 20 to 22, wherein
the carbon-containing gas is free of halogens.

### Aspect 24

The etching method according to any one of aspects 20 to 23, wherein
the substrate receives ions having an energy level of 1 keV or less.

### Aspect 25

An etching device, comprising:
a chamber;
a substrate support in the chamber;
a plasma generator; and
a controller configured to perform control operations including
   (a) providing a substrate onto the substrate support, the substrate including an etching target film and a mask on the etching target film, the mask including at least one opening,
   (b) forming a deposition film including a group 14 element on a surface of the substrate,
   (c) heating the deposition film to a temperature higher than or equal to a glass transition temperature and performing a thermal reflow treatment on the deposition film, and
   (d) etching the etching target film.

The above embodiments are mere examples described for illustrative purposes and are not intended to limit the scope of the present disclosure. The embodiments may be modified in various manners without departing from the spirit and scope of the present disclosure. For example, one or more components in one embodiment may be added to the structure according to another embodiment. One or more components in one embodiment may be replaced with the corresponding one or more components in another embodiment.

Reference to an element in the singular is not intended to mean “one and only one” unless explicitly so stated, but rather “one or more.” Moreover, where a phrase similar to “at least one of A, B, or C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C.

No claim element herein is to be construed under the provisions of 35 U.S.C. 112(f) unless the element is expressly recited using the phrase “means for.” As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

The scope of the invention is indicated by the appended claims, rather than the foregoing description.

1. An etching method, comprising:
(a) providing a substrate, the substrate including an etching target layer and a mask on the etching target layer, the mask including at least one opening;
(b) forming a deposition layer including a group 14 element on a surface of the substrate;
(c) heating the deposition layer to a temperature higher than or equal to a glass transition temperature and performing a thermal reflow treatment on the deposition layer; and
(d) etching the etching target layer.

2. The etching method according to claim 1, wherein (c) is performed after (b).

3. The etching method according to claim 2, wherein
(b) includes forming the deposition layer by chemical vapor deposition, atomic layer deposition, or molecular layer deposition.

4. The etching method according to claim 2, wherein
(c) includes heating the deposition layer using at least one selected from the group consisting of a heater, a lamp, a plasma, electron beams, and ion beams.

5. The etching method according to claim 2, wherein a cycle including (b) and (c) is repeated.

6. The etching method according to claim 1, wherein
(b) and (c) are performed simultaneously or in an order of (b) and (c).

7. The etching method according to claim 6, wherein
each of (b) and (c) includes exposing the substrate to a plasma generated from a first processing gas including a group 14 element.

8. The etching method according to claim 7, wherein
the first processing gas includes a halogen.

9. The etching method according to claim 1, wherein (d) is performed after (c).

10. The etching method according to claim 9, wherein
(c) and (d) are performed using a plasma,
(c) includes providing no bias signal to a substrate support, and
(d) includes providing a bias signal to the substrate support to irradiate the surface of the substrate with ions.

11. The etching method according to claim 9, wherein
a cycle including (c) and (d) is repeated.

12. The etching method according to claim 1, wherein
(c) and (d) are performed simultaneously.

13. The etching method according to claim 12, wherein
each of (c) and (d) includes exposing the substrate to a plasma generated from a second processing gas including an etching gas.

14. The etching method according to claim 13, wherein
the second processing gas includes a halogen.

15. The etching method according to claim 1, wherein
(b), (c), and (d) are performed in an order of (b), (c), and (d).

16. The etching method according to claim 15, wherein
a cycle including (b), (c), and (d) is repeated.

17. The etching method according to claim 1, wherein
(b), (c), and (d) are performed simultaneously.

18. The etching method according to claim 17, wherein
each of (b), (c) and (d) includes exposing the substrate to a plasma generated from a third processing gas including a group 14 element and an etching gas.

19. The etching method according to claim 18, wherein
the third processing gas includes a halogen.

20. The etching method according to claim 18, wherein
the third processing gas includes a hydrogen halide gas and a carbon-containing gas.

21. The etching method according to claim 20, wherein
the hydrogen halide gas has a volume percent of 85% or greater of the third processing gas, excluding a noble gas and a nitrogen gas in the third processing gas.

22. The etching method according to claim 20, wherein
the carbon-containing gas has a volume percent of 10% or less of the third processing gas.

23. The etching method according to claim 20, wherein
the carbon-containing gas is free of halogens.

24. The etching method according to claim 20, wherein
the substrate receives ions having an energy level of 1 keV or less.

25. An etching device, comprising:
a chamber;
a substrate support in the chamber;
a plasma generator; and
controller circuitry configured to perform control to
(a) provide a substrate onto the substrate support, the substrate including an etching target layer and a mask on the etching target layer, the mask including at least one opening,
(b) form a deposition layer including a group 14 element on a surface of the substrate,
(c) heat the deposition layer to a temperature higher than or equal to a glass transition temperature and performing a thermal reflow treatment on the deposition layer, and
(d) etch the etching target layer.
